(19) United States
(12) Patent Application Publication
(10) Pub. No.: US 2004/0141386 A1
(43) Pub. Date: Jul. 22, 2004

(54) Upgrading field programmable gate arrays overs data-communication networks

(76) Inventor: Peter Karlsson, Molndal (SE)

Correspondence Address: NIXON & VANDERHYE, PC, 1100 N GLEBE ROAD, 8TH FLOOR, ARLINGTON, VA, 22201-4714, US

(21) Appl. No.: 10/481,432

(22) PCT Filed: Jun. 11, 2002
(86) PCT No.: PCT/SE02/01124

(30) Foreign Application Priority Data
Jun. 20, 2001 (SE) 0102199-7

(51) Int. Cl. G11C 7/00

(52) U.S. Cl. 365/200

(57) ABSTRACT

A terminal comprising a partially re-configurable Gate Array, FPGA, being capable of being partitioned into at least first and second separate functionnal blocks, (FPGAx, FPGAy) is provided. The terminal comprises a non-volatile memory (NVMEM), at leasst one interface (IF) for establishing cimmunication with an external server (SRV) over a data network, preferably using the IP and TCP suite of protocols and an operational unit (OPUT). The first functional block (FPGAx) comprises functionality relating to establishing connectivity and downloading of load modules (B, B′, B″) from the external server (SRV). The second functional block (FPGAx) comprises application specific funtionality for operating together with the opertional unit (OPUT), the load modules (B, B′, B″) defining the functionnality of the second functional block (FPGAy) and being downloadable through the first functinal block (FPGAx).

### FIELD OF THE INVENTION

The present invention relates generally to an upgrading of the functionality of field programmable gate arrays over data networks.

### BACKGROUND OF THE INVENTION

With the ever increasing pace of new standards and software versions evolving, software upgrading over the Internet is a very practical way of keeping up to date. Downloading can be done whenever a network connection is available and can be made subject to either pushing or polling.

As software can be downloaded and updated, also the hardware-like functionality of Field Programmable Gate Arrays (FPGA) can be downloaded over the Internet or over other suitable data network connections.

FPGA devices are typically used for real time processing requirements because of the high speed facilitated by the parallel operations enabled by a FPGA or in smaller processing applications where a microprocessor would be too expensive. Moreover, FPGAs have low power consumption.

As is well known, an FPGA is a component device that comprises a network of standardised device specific Control Logic Blocks (CLB) and Programmable Switch Matrices (PSM). The functionality of the device can be tailored by a suitable design process, involving a pick and place step where logic functions in each individual CLB is identified and selected and suitable routing between the respective CLBs is accomplished via the respective PSMs.

A multimedia Internet access terminal demonstration application, NMT 2000, by Celoxica™, described on www.celoxica.com, November 2000 is based on Xilinx™ FPGA's and configured through a Handel-C design environment. An outline of this device is shown in FIG. 1.

The above device comprises a touch sensitive LCD screen, speakers (SP), an audio driver (AD), a screen driver (SD), a microphone (MIC), a local port (LP), an Ethernet™ port (EN) and a Bluetooth™ (BT) interface, two Field Programmable Gate Arrays (FPGA1, FPGA2), a random access memory (RAM), a non volatile memory (FLASH) and provides functionality such as voice communication over IP and MP3 downloading over TCP/IP. New hardware functionality can be downloaded from a server (SRV) over the Internet for reconfiguring the applications.

Prior art document “Field Upgradable Hardware and Software Systems”, “Enabling Technology from GoAhead Software and Xilinx, Feb. 1, 2000, http://www.xilinx.com/xilinxonline/partners/fuwhpaper.pdf, discloses a system which is upgradable over the Internet, comprising an interface, a microprocessor, a FPGA and three non volatile storages.

The above system has been illustrated in FIG. 2. The non-volatile storage 1 contains firmware for the microprocessor. The system is designed so that there is always a last known-good configuration for the FPGA. This is handled by the redundancy of the non-volatile storage 2 and 3. In a usual sequence of events, the FPGA will be initially configured from the non-volatile storage 2. When an upgrade is requested, it is downloaded in non-volatile storage 3. The FPGA is then reconfigured from this location. The program controlling the programming of the FPGA then switches the functions of these two storage areas as non-volatile storage 3 is now the known-good configuration and non-volatile storage 2 is now ready to contain the next upgrade.

In prior art document XAPP151 (v1.3), Feb. 22, 2000, by Xilinx® a Virtex™ Series FPGA configuration architecture has been described. The configuration architecture enables a partial reconfiguration which involves that when using a certain bit location in a configuration bit stream containing a mix of commands and data, on-chip data can be individually accessed and altered without stopping the function loaded in the device. Hence, if there are more than one function implemented in the FPGA, one or more functions can be examined or changed without disturbing the function of the other functions implemented. This requires of cause that the functions are independent. New functions can also be added to the FPGA, which means that the lifetime of a design can be increased in a simple way.

### SUMMARY OF THE INVENTION

The invention seeks to provide a cost effective reconfigurable terminal.

This object has been achieved by the subject matter of claim 1.

It is another object to provide further cost reductions of a reconfigurable terminal.

This object has been achieved by the subject matter of claim 2.

It is another object to set forth a method for updating reliably load modules of the terminal above.

This object has been provided by the method according to the subject matter of claim 4.

Further advantages will appear from the following detailed description of the invention.

### BRIEF DESCRIPTION OF THE DRAWINGS

FIG. 1 shows a block diagram of a prior art access terminal,

FIG. 2 shows a block diagram of a prior art system,

FIG. 3 shows a first preferred embodiment of a terminal according to the invention,

FIG. 4 shows a second preferred embodiment of a terminal according to the invention, and

FIG. 5 shows a flow diagram of operation of the terminal shown in FIG. 3.

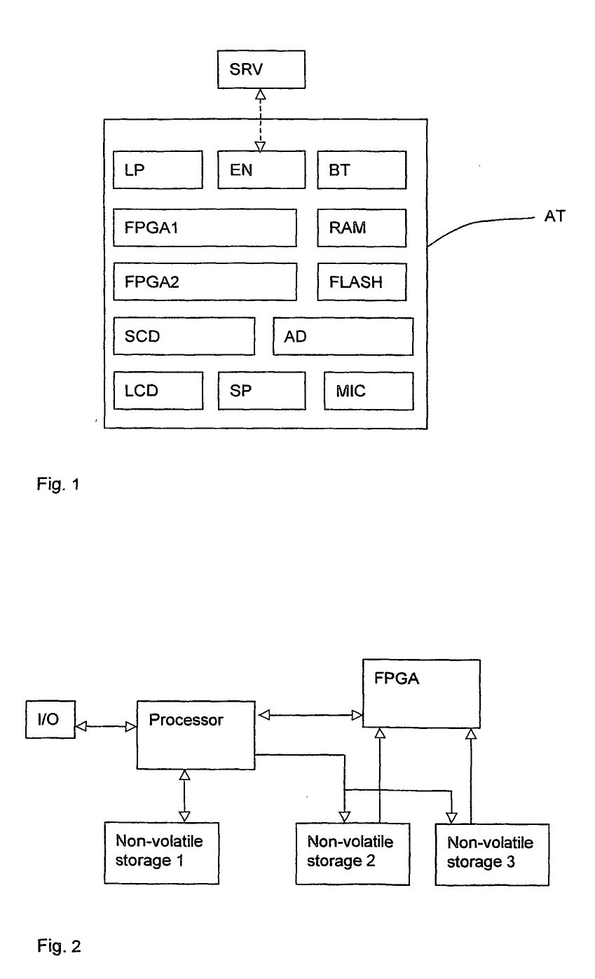

### DETAILED DESCRIPTION OF PREFERRED EMBODIMENTS OF THE INVENTION

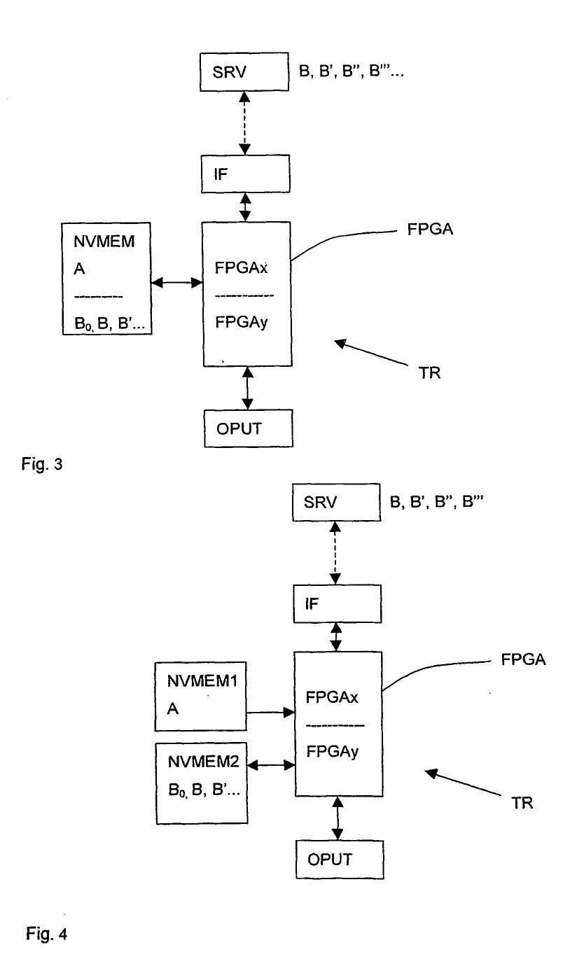

In FIG. 3, a preferred embodiment of a terminal, TR, according to the invention has been shown. The terminal comprises a Field Programmable Gate Array, FPGA, being capable of being partitioned into at least a first and a second separate functional block, FPGAx and FPGAy, a non-volatile memory, NVMEM, such as a FLASH RAM (Random Access Memory), at least one interface (IF), such an Ethernet interface or wireless interfaces, for establishing communication with an external server (SRV) over a data network, preferably using the IP and TCP suite of protocols and an operational unit (OPUT).

For instance, a Xilinx® Virtex™ series FPGA, featuring partial reconfiguration is used.

The task of the first functional block, FPGAx, is to establish communication with the external server, over the interface (IF) preferably using the IP (Internet Protocol) and TCP (Transport Control Protocol) suite of protocols for connectivity and downloading. The load module or configuration setting enabling the functional block FPGAx to perform the above task is (initially) stored in the non-volatile memory NVMEM, but this information could also be stored in a separate Read Only Memory (ROM) device. It is well known in the art to implement the above functionality in a Field Programmable Gate Array.

The task of the second functional block, FPGAy is specific for the particular application. The functional block FPGAy and the operational unit, OPUT, could for instance relate to a multimedia terminal as shown in FIG. 1. In this case, the operational unit OPUT shown in FIG. 3 could correspond to the functions: Screen driver, SCD, audio driver, AD, LCD-display, speaker, SP and microphone, MIC.

The actual functionality of FPGAy and the operational unit, OPUT, are virtually endless. Other examples of applications could relate to relative complex industrial applications like a central controller in a base station for mobile communication or simpler monitoring devices or apparatus. A consumer electronic platform capable of handling various audio, video and game formats is another possible application. In general, the functionality could relate to any device, which needs to be up-dated.

For some professional applications, such as radio base stations, it is important that service outages are kept at a minimum, since service outages correspond to income losses for the operator. Hence, it is important that updates and repairs to the operational unit can be done with little or no interruption.

Various versions of configuration settings or load modules (B, B′, B″, B′″ . . .) are to be stored in the non-volatile memory, NVMEM, for loading into the second functional block.

The terminal, TR, is arranged such that a first entity is formed by the first functional block and the interface, IF, and a second entity formed by the second functional block, FPGAy, and the operational unit, OPUT. These entities function independently of one another. If one entity malfunctions the other can still function.

The FPGA is divided into at least two separate functional blocks as explained in the section background of the invention. Moreover, the FPGA used is of the partially reconfigurable type, which makes it possible to load a new load module into one block of the FPGA while the other block is running.

FIG. 4 shows an embodiment of the invention where the memory is divided into two memories. A first memory NVMEM1 serves the first functional block FPGAx exclusively, while the second memory NVMEM serves the second functional block exclusively. The first memory is for instance a read only memory, whereby it is not possible to tamper with the functionality of establishing connectivity with the external server. Thereby, the security has been enhanced.

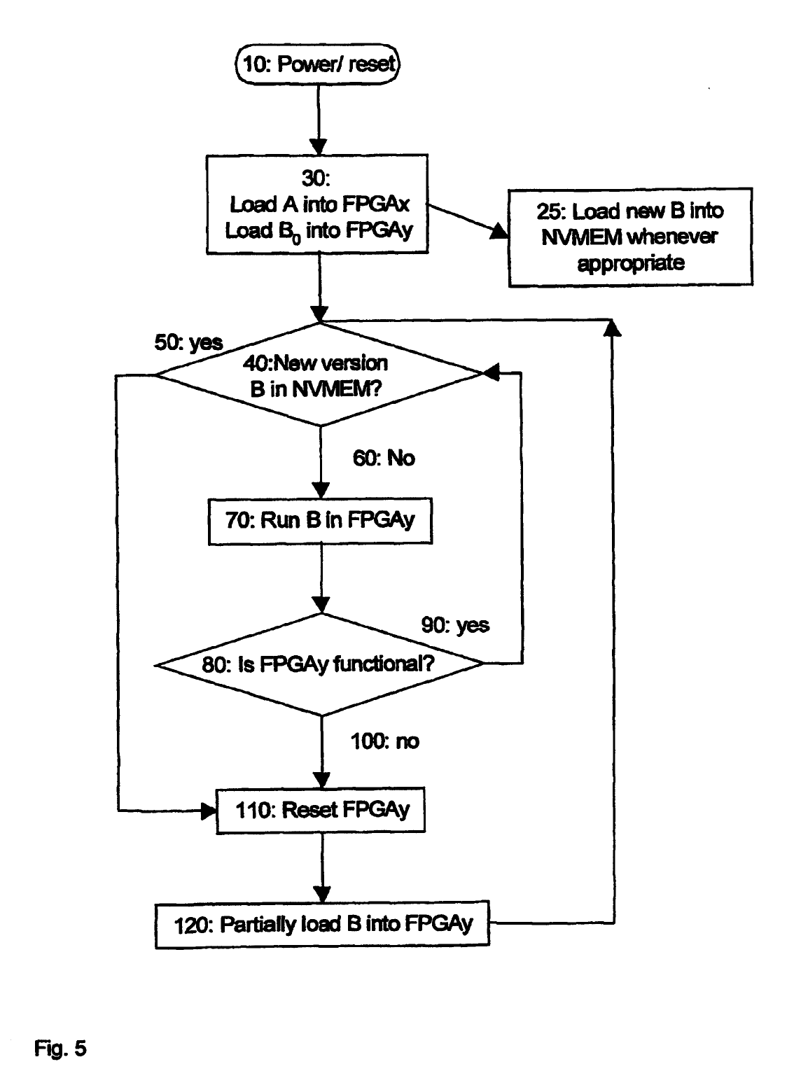

Returning to the embodiment shown in FIG. 3, the above mentioned versions of load modules are downloaded from the server SRV through the interface IF by means of the first functional block, FPGAx, into the non-volatile memory, NVMEM, in a manner, which shall be explained with reference to the routine shown in FIG. 5.

In step 10, the terminal TR is powered on or reset.

In step 30, the load modules A and B₀ are loaded into each respective functional block FPGAx and FPGAy. Subsequently, a loop is started in step 25, which regularly polls the server SRV for information on whether a new version, B, B′, B″ is available and if this is the case downloads the new version into the non-volatile memory NVMEM.

The function A in the non-volatile memory NVMEM should preferably not be updated. The reason is that if the update fails for some reason, for instance power down, the functionality is lost and a new version of A can not be re-loaded from the server SRV. A problem during the update of B can be handled since the function A always can load a new version of B from the server SRV to the non-volatile memory NVMEM.

In a subroutine beginning from step 40, it is checked whether a more recent version of B is available in the memory NVMEM than implemented in the second functional block FPGAy.

If this is the case, step 50, the routine goes to step 110 where the second functional block FPGAy is reset.

If this is not the case, step 60, the routine continues in step 70 where the current version of B is run in FPGAy.

A self-test or error determination is run in step 80. If no errors are found and the functionality of FPGAy with its current version of B is found to operate satisfactorily, the routine carries on running FPGAy and waits for a newer version of B being loaded into the memory NVMEM.

If the FPGAy is found not to operate in a functional way, the routine continues to step 110 where the operation is halted and FPGAy is reset.

Subsequently, in step 120, the current version of B is loaded into FPGAy and the routine goes to step 40 where the above steps are continued.

The same function, an upgradable function, could of cause also be implemented in two separate FPGAs. However, it is often more cost efficient to select one larger FPGA than two small FPGAs having a total capacity equalling the large FPGA. The present invention offers this advantage to FPGA upgradable terminals.

1. Terminal comprising a Field Programmable Gate Array, FPGA, being partitioned into at least first and second separate functional blocks (FPGAx, FPGAy), a memory (NVMEM, NVMEM1, NVMEM2), at least one interface (IF) for establishing communication with an external server (SRV) over a data network, preferably using the TCP and IP suite of protocols, and an operational unit (OPUT), wherein
the Field Programmable Gate Array is partially reconfigurable,
the first functional block (FPGAx) is reconfigurable by a first load module (A) which comprises functionality relating to establishing connectivity over the internal interface (IF) with an external server (SRV),
the second functional block (FPGAy) is reconfigurable by a second load module (B, B′, B″) which comprises application specific functionality for operating together with the operational unit (OPUT), said second load modules (B, B′, B″) defining the functionality of the second functional block (FPGAy),
the second load modules (B, B′, B″) being downloadable from the external server (SRV) through the first functional block (FPGAx),
wherein the first functional block (FPGAx) and the interface (IF) functions independently of the second functional block (FPGAy) and the operational unit (OPUT), and vice versa, and that the first functional block may be running while the other functional block is reconfigured.

2. Terminal according to claim 1, whereby both the first load module (A) and the second load module (B), are stored in the memory (NVMEM).

3. Terminal according to claim 3, wherein the memory is partitioned into two separate memories, whereby a first memory (NVMEM1) serves the first functional block FPGAx exclusively, while the second memory (NVMEM2) serves the second functional block exclusively.

4. Method of updating load modules in the system according to claim 1-3,
loading modules A and B₀ partially into each respective functional block (FPGAx, FPGAy),
repeating a subroutine in which
regularly downloading new versions of the load module of the second functional block (B, B′, B″) into the memory (NVMEM, NVMEM2),
checking whether a more recent version of the load module for the second functional block (B, B′, B″) is available in the memory (NVMEM, NVMEM2) than implemented in the second functional block (FPGAy), and
if this is the case, resetting the second functional block (FPGAy), and partially loading the new B into the second functional block (FPGAy) and running the new version of B in the second functional block,
if this is not the case, running the current version of B in the second functional block (FPGAy).

5. Method according to claim 4, wherein in the subroutine it is tested whether the second functional block (FPGAy) with its current version of the load module for the second functional block (B, B′, B″) is functional, and if this is not the case, resetting the second functional block (FPGAy) and partially loading a new load module for the second functional block (B, B′, B″) into the second functional block when available.
